(19) United States
(12) Patent Application Publication
(10) Pub. No.: US 2007/0017659 A1
(43) Pub. Date: Jan. 25, 2007

(54) Heat spreader

(75) Inventors: Thomas J. Brunschwiler, Thalwil (CH); Urs Kloter, Dietikon (CH); Ryan Joseph Linderman, Zurich (CH); Bruno Michel, Adliswil (CH); Hugo E. Rothuizen, Adliswil (CH)

Correspondence Address: Anne Vachon Dougherty, 3173 Cedar Road, Yorktown Hts, NY, 10598, US

(73) Assignee: International Business Machines Corporation, Armonk, NY (US)

(21) Appl. No.: 11/476,516

(22) Filed: Jun. 28, 2006

(30) Foreign Application Priority Data
Jun. 29, 2005 (EP) 05014125.8

(51) Int. Cl. H05K 7/20

(52) U.S. Cl. 165/80.4; 361/699; 165/104.33

(57) ABSTRACT

A flexible, self-contained active multi-phase heat spreader apparatus for cooling electronic components, the heat spreader having fluid sealed between two plates and a pumping mechanism to actuate multi-phase flow of the fluid. Thermal energy from an electronic component in contact with the heat spreader is dissipated from a core region via the working fluid to the entire heat spreader, and then to a heat sink. Surface enhancement features located between the two plates aid transfer of thermal energy from a first metal plate into the fluid.

### FIELD OF THE INVENTION

This invention relates to a heat spreader and particularly relates to active heat spreaders in contact with microprocessor chips.

### TECHNICAL BACKGROUND

In the field of microprocessor chip packages, an effective transfer of thermal energy from a microprocessor chip to a heat sink is important for thermal management of the microprocessor chip.

Generally, the heat sink is of relatively larger area than the microprocessor chip and can be cooled by forced air conduction. The thermal energy is transferred to the passive heat sink solely by heat conduction through solid structures. Generally, these structures are metal and so the thermal resistance of the metal scales inversely with the cross-sectional area of the conduction path, resulting in a temperature difference between the microprocessor chip and the periphery of the heat sink which mitigates efficiency. Other materials for the heat sink may be considered, for example, diamond has a relatively low thermal resistance which would make it a suitable material for a large area heat sink. However, this is a costly material which is difficult to pattern in 3-dimensions; and, an additional thermal interface would be required for the conduction of thermal energy from the microprocessor chip to the diamond heat sink.

As an alternative to the passive heat spreader technique, impingement cooling and microchannel cooling are also known in the art. Impingement cooling involves liquid flowing through channels that impinge normal to the back side of a microprocessor chip. Microchannel cooling involves liquid flowing through parallel channels along the back side of a microprocessor chip, wherein the liquid is subject to forced convection. Both techniques require an external pump to circulate the liquid between the back side of the microprocessor chip, where heat is absorbed, and a radiator. Heat is subsequently dissipated from the radiator to ambient using a fan and an air heat exchanger. Disadvantages of these cooling techniques include the relatively large weight and size of the apparatus, which makes them incompatible with portable systems. The pump causes increased noise levels and reduced system reliability. Further, at each interconnect (i.e., between chip, pump and heat exchanger) a pressure drop is experienced which reduces overall system efficiency. The necessary fluidic fixtures, pumps, sealing and system assembly are costly.

Another known cooling device is an active linear heat spreader device, which uses sinusoidally oscillating flow of a working fluid along a network of tubes. U.S. Pat. No. 6,631,077 discloses an active heat spreader for microprocessor chip cooling. It comprises a plate with a plurality of interconnected parallel channels, a reservoir at a first end of the plate and an oscillator at a second end of the plate. A cover seals a working fluid into the channels, reservoir and oscillator, the working fluid having liquid phase flow or liquid-vapour phase flow. The heat spreader is thermally coupled to the microprocessor chip via a heat transfer medium.

In U.S. Pat. No. 6,655,450, a heat pipe for cooling electronic elements is disclosed which utilises forced oscillatory linear flow of a charged liquid. In the heat pipe body, a closed loop flow path meanders between a heat absorbing section and a heat radiating section. A mechanism to cause the oscillatory flow is sealed at the connection between the two ends of the heat pipe. This mechanism may be a vibrator, a solenoid or a diaphragm.

These active linear heat spreader designs are known to provide effective thermal conductivity along the length of the liquid-filled channels due to a relatively high heat flux between the hot and cold reservoirs. However, the high heat flux occurs only when the flow rate reaches the peak of oscillation and a poor heat flux occurs when the flow stops between cycles.

Such linear oscillating flow systems utilize “undeveloped” flow profiles. These flow profiles are characterized by a region at the center of a channel that has a nearly uniform flow speed with a viscous boundary layer attached to the channel walls. This plug-like velocity profile is achieved using an appropriate frequency of oscillations for a given working fluid and fluidic gap (i.e., channel depth). The undeveloped flow profile allows the heat contained in the region having the plug-like profile to be transported farther along the channel before the heat is absorbed radially. Thus, a higher degree of mass transport is created compared to a parabolic-type flow profile. Depending on the thermal diffusivity of the working fluid, an undeveloped thermal profile can also be induced which further enhances the heat transferred by the plug-like velocity profile. In order to theoretically predict the conditions required for the undeveloped flow profiles, analytic models for viscous laminar flows within circular channel are used. Two key dimensionless parameters based on the velocity and thermal boundary layers are used to estimate the flow profiles. First, for a thin velocity boundary layer condition to be met, a Womersley number is defined:

$${W}_{o} = \frac{H}{2} \cdot \sqrt{\frac{ω \cdot ρ}{η}} \qquad ( 1 )$$

where η, ρ, ω, and H represent the fluid dynamic viscosity, density, oscillation frequency and channel diameter respectively. When Wₒ>>1, a plug-like velocity profile is expected with a viscous boundary at the side walls. Because heat transfer is also of interest, the temperature profile should also be similar to the plug-like velocity profile and is defined using another dimensionless number, α [5]:

$$α = \frac{H}{2} \cdot \sqrt{\frac{ω \cdot ρ \cdot {C}_{p}}{k}} \qquad ( 2 )$$

where k and Cₚ represent the fluid thermal conductivity and specific heat capacity respectively. For α >>1, a region of uniform temperature exists at the channel centerline similar to the condition above for the velocity profile. In order to achieve the plug-like velocity profile for a working fluid of relatively high thermal conductivity, for example liquid metal, and a relatively large fluidic gap, an appropriate frequency of oscillations would be higher than for a working fluid of water or oil. Thus, practical application may be limited. For maximum performance both Wₒ and a should be substantially greater than 1. The problem encountered with such flow velocity profiles is that a relatively large pumping power is required in order to further increase Wₒ and α. Known linear oscillating flow heat spreaders utilize an efficiency relationship to define optimum heat spreader performance which takes into account oscillation frequency and amplitude. According to U. H. Kurzweg in “Enhanced heat conduction in oscillating viscous flows within parallel-plate channels”, J. Fluid Mech. (1985), vol. 156, pp. 291-300, the most efficient operation for linearly oscillating flow between parallel plates at a fixed operating frequency, occurs approximately when:

$${W}_{o}^{2} \cdot Pr = {W}_{o}^{2} \cdot ( \frac{η \cdot {C}_{p}}{k} ) = \frac{{H}^{2} \cdot ω \cdot ρ \cdot {C}_{p}}{4 k} = π \qquad ( 3 )$$

where Pr represents the Prandtl number. It is also shown theoretically that for an oscillating flow system operating at maximum efficiency, the heat flux between hot and cool reservoirs, with a tidal displacement S, scales as:
q˜ΔTωS² 4)
where q and ΔT represent heat flux and reservoir temperature difference, respectively.

A problem associated with conventional microprocessor chip cooling techniques is a result of the warpage in a microprocessor chip when heated. This warpage causes the gap between a microprocessor chip and a heat sink to enlarge, thus resulting in a significantly increased thermal resistance to ambient. It is common in the fabrication of microprocessor chip packages to use thick rigid plates or lids, which further compounds this problem and also adds significant mass to a package. Additionally, as the warpage of a microprocessor chip changes during hot and cold states, any thermal interface material between the microprocessor chip and heat sink is subject to a pumping action, in an effect known as “paste pumping”. Over many operating cycles, this effect gradually degrades the thermal interface material and hence the reliability of the interface.

It is an aim of the present invention to provide a heat spreader which mitigates the problems of the known art.

### SUMMARY OF THE INVENTION

According to a first aspect of the present invention there is provided a heat spreader comprising a chamber comprising first surface, a second surface, and chamber sidewalls and a fluid sealed in the chamber, characterized in that at least two actuators are disposed in the chamber and the operational phase of the actuators results in a substantially constant velocity of fluid flow across a core region of the heat spreader. Advantageously, the heat spreader is a self-contained cooling device which may directly interface with a microprocessor chip, and the heat spreader cross-section is relatively thin enabling the heat spreader to deform to accommodate microprocessor chip warpage.

Preferably, the direction of the fluid flow changes radially and the at least two actuators are one of four actuators which drive a two-phase flow cycle, six actuators which drive a three-phase flow cycle, and multiple actuators which drive a respective multi-phase flow cycle. Advantageously, the heat spreader has an effective thermal conductivity several times higher than diamond.

Each actuator preferably comprises a reservoir of the fluid and a membrane interfacing between an actuation means and the reservoir, and may additionally comprise a further membrane positioned on the opposite side of the reservoir from the actuation means. Thus, quiet and efficient operation is provided, and external pumps are not required.

The core region is preferably positioned centrally within the heat spreader and the actuators are positioned at the periphery of the heat spreader.

Surface enhancement features may be positioned on at least one of the first surface and the second surface, and may comprise a plurality of protrusions in a distributed arrangement, whereby the shape of the protrusions and the distributed arrangement provide a substantially uniform flow resistance along all radial flow directions. Preferably, the distributed arrangement is located at the core region. Further, the surface enhancement features may comprise at least one flow directing feature having a form of a barrier positioned to provide substantially uniform flow of the fluid throughout the heat spreader, and the at least one flow directing feature may be located in an area between the core region and the actuators.

The fluid may be one of water, oil, a magnetic liquid and a conductive liquid.

According to a second aspect of the present invention there is provided a heat shuttle comprising a head portion fixed to a surface via a mobile stem portion, where by the heat shuttle transfers thermal energy between the surface and a fluid circulating around the head portion. In a preferred embodiment, the heat shuttle is a surface enhancement feature in a heat spreader of the present concept. Advantageously, thermal conductivity between the first and second surfaces of the heat spreader and the fluid is enhanced because the effective surface area from which heat is transferred into the fluid is enlarged by the heat shuttle.

According to a third aspect of the present invention there is provided a method for transferring heat away from a heat source, the method comprising the steps of providing a chamber, comprising first surface, a second surface and chamber walls, and a fluid sealed in the chamber between the first and second surfaces, and at least two actuators integral to the arrangement, and having the chamber in contact with the heat source, an actuating step for actuating the actuators, such that the operational phase of the actuators results in a substantially constant velocity of fluid flow across a core region of the arrangement.

The use of the term ‘phase’ in the following description refers to a fraction of a cycle of a periodic waveform which has been completed at a specific reference time, and not to the state of a substance, namely solid, liquid or gas.

### BRIEF DESCRIPTION OF THE DRAWINGS

Embodiments of the present invention will now be described, by way of example only, with reference to the accompanying drawings in which:

FIG. 1 depicts an enlarged schematic plan view of an embodiment of an active multi-phase heat spreader of the present invention;

FIG. 2 shows a cross-sectional view of an embodiment of an active multi-phase heat spreader in contact with a heat sink and a microprocessor chip;

FIG. 3a shows a schematic illustration of a two-phase actuated flow cycle;

FIG. 3b shows a schematic illustration of three-phase actuated flow cycle;

FIG. 4 indicates working fluid movement during part of a two-phase actuated flow cycle;

FIG. 5 shows a plan view of a section of spreading area and reservoirs of an active multi-phase heat spreader showing flow directing features;

FIG. 6 illustrates three alternative arrangements of surface enhancement features within the core region;

FIG. 7a depicts a side view of a first embodiment of a heat shuttle during three stages of a flow cycle;

FIG. 7b depicts a side view of a second embodiment of a heat shuttle during three stages of a flow cycle;

FIG. 8 shows a plan view of an exemplary embodiment of a series of patterned plate layers;

FIG. 9a shows a cross-sectional view of a preferred embodiment of an active multi-phase heat spreader;

FIG. 9b shows a cross-sectional view of a further preferred embodiment of an active multi-phase heat spreader;

FIG. 10 is a graphical illustration showing drive frequency in Hertz against the fluidic gap in meters with respect to liquid metal, water and oil as working fluids; and

FIG. 11 depicts a schematic illustration of symmetric membrane actuation in the fluidic gap of a reservoir.

### DETAILED DESCRIPTION OF THE INVENTION

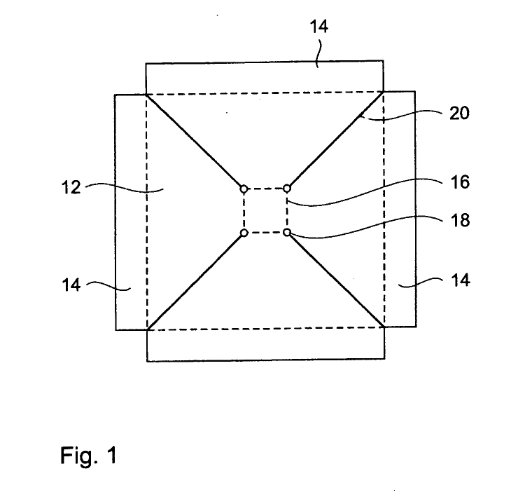

FIG. 1 shows a plan view of an active multi-phase heat spreader 10, and specifically an active two-phase heat spreader. A square spreading area 12 has a rectangular reservoir 14 at each of the four peripheral edges. A square core region 16 is located at the centre of the heat spreader 10 and has approximately the same dimensions as a microprocessor chip which is positioned below the heat spreader 10. For example, where the core region 16 has an area of approximately 1 cm×1 cm, a spreading area 12 of approximately 15 cm×15 cm may be utilized. Four mounting holes 18 are provided at the corners of the core region 16, and a flow directing feature 20 joins each mounting hole 18 to the nearest spreading area corner.

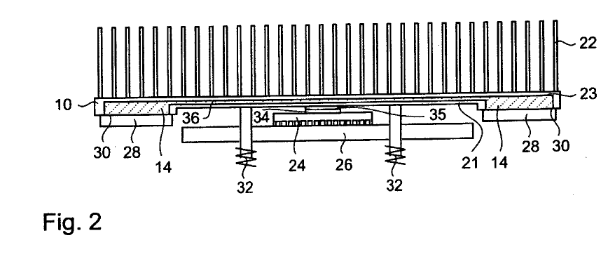

FIG. 2 shows a cross-sectional view of an embodiment of the active multi-phase heat spreader 10 in contact with a large area heat sink 22 and a microprocessor chip 34. The microprocessor chip 34 is mounted on a microprocessor chip carrier 24 which is further attached to a printed circuit board 26. The microprocessor chip 34 is positioned approximately below the core region 16 of the active multi-phase heat spreader 10. Several actuators 28, also referred to as actuation means, are utilized, each positioned in contact with a membrane cover 30 over a reservoir 14, of which two are seen in this cross-sectional view. Four spring-loaded plungers 32, of which two are seen in this view, pass through the printed circuit board 26 and through the mounting holes 18 in the active multi-phase heat spreader 10 and act to hold the components in mechanically biased contact. An area of thermal interface material 35 is located between the uppermost surface of the microprocessor chip 34 and the adjacent surface of the heat spreader 10. The heat spreader 10 is generally fabricated from layers of metal and has a relatively thin total depth, which results in an elastic quality. A gap, known as a fluidic gap 36, is provided between a first layer of the heat spreader 10, also referred to as a first surface 21, and a second layer of the heat spreader 10, also referred to as a second surface 23, and a working fluid 38 is sealed into the fluidic gap 36. In preferred embodiments, a fluidic gap may be in the range of approximately 0.01 mm-1.0 mm. The working fluid 38 may be, for example, water, oil or a magnetic or conductive liquid.

In operation, a substantial proportion of heat generated by the microprocessor chip 34 is conducted via the thermal interface material 35 into the working fluid 38 in the fluidic gap 36 at the core region 16 of the heat spreader 10. The working fluid 38 is driven through the fluidic gap 36 by a flow created by the venting and filling of the reservoirs 14, where each reservoir operation is initiated by the contacting actuator 28 moving the membrane 30. The resultant two-phase actuated, radially oscillating flow pattern causes a constant flow speed across the core region 16 and distributes heat absorbed by the working fluid 38 in a radial direction and across the entire area of the heat spreader 10. Also, boiling-enhanced cooling may be involved in the distribution of heat from the core region 16. Specifically, vapor forms in the fluidic gap 36 at the core region 16 and is distributed via the oscillating working fluid motion.

The primary heat path from the heat spreader 10 to ambient is primarily via the entire uppermost plate of the heat spreader, which generally forms the base of a conventional heat sink. Thus, heat is transferred from the core region 16, the spreading area 12 and the reservoirs 14, into the conventional heat sink. For example, where heat density at the core region is approximately 300 Watts/cm², then heat density will be approximately 1.3 Watts/cm² for the entire uppermost plate of the heat spreader. This heat density can be dissipated via forced air cooling.

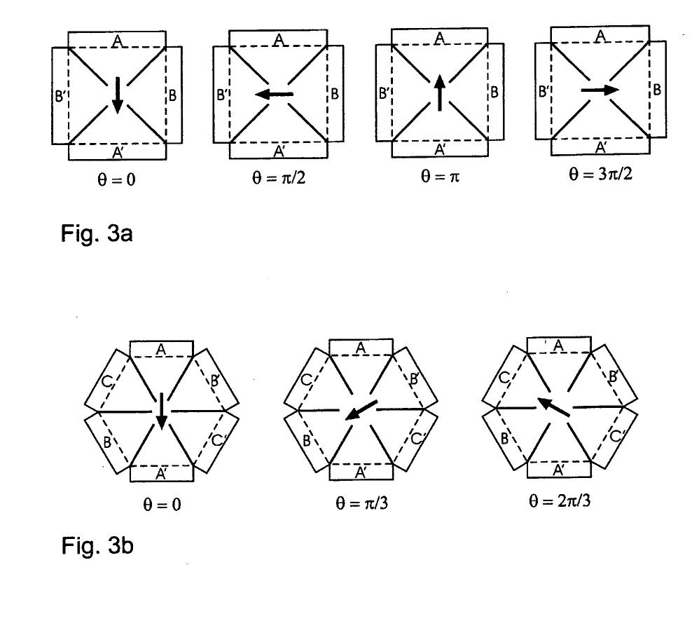

Specifically, the two-phase actuated, radially oscillating flow pattern occurs in the following way, described with reference to FIG. 3a. The four reservoirs notated A, A′, B, B′ are driven by the actuators at 90 degrees out of phase. Specifically, as flow in the A-A′ reservoirs begins to decay to zero, the flow between the B-B′ reservoirs is reaching a maximum, and the flow rotates radially. Thus, the flow direction rotates 360 degrees during one complete cycle. Advantageously, the constant flow speed across the core region of the active two-phase system is at the maximum value of the active single-phase system.

FIG. 3b schematically shows a plan view of an active three-phase heat spreader of the present concept, wherein six rectangular reservoirs are located at the peripheral edges of a hexagonal spreading area. The three-phase actuated, radially oscillating flow pattern occurs in a similar fashion to the two-phase actuated radially oscillating flow pattern. Namely, the six reservoirs notated A, A′, B, B′, C, C′ are driven by the actuators at 60 degrees out of phase. Specifically, as flow in the A-A′ reservoirs begins to decay to zero, the flow between the B-B′ reservoirs is reaching a maximum, and then as flow in the B-B′ reservoirs begins to decay to zero, the flow between the C-C′ reservoirs is reaching a maximum. Again, the flow rotates radially as indicated by the solid arrows on FIG. 3b.

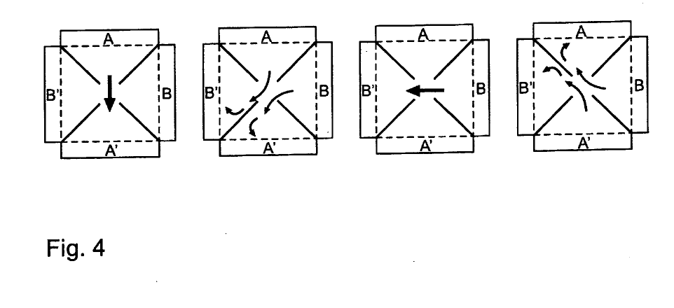

FIG. 4 illustrates the circulation of the working fluid within the heat spreading area during two of the intermediate phases of an active two-phase system.

Advantageously, active three-phase and higher multi-phase heat spreaders provide heat spreading of greater uniformity than an active two-phase heat spreader.

Further measures to provide efficient heat spreading include the addition of flow directing features located in the spreading area 12 and also surface enhancement features located in the core region 16.

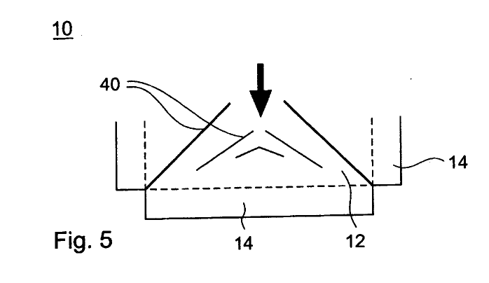

FIG. 5 depicts a plan view of a portion of an active two-phase heat spreader 10 showing flow directing features 40. Generally, these are barriers of varying lengths attached between a lower plate and an upper plate in the fluidic gap 36 of the heat spreader 10. Various designs are possible dependent upon the shape of the spreading area 12 and whether the flow directing features 40 have a mechanical secondary role in maintaining a uniform fluidic gap 36.

In operation, the flow directing features 40 aid the uniform flushing of the spreading area 12 with working fluid 38 and also the elimination of flow stagnation zones.

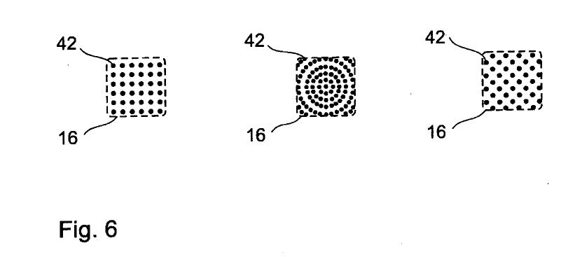

FIG. 6 shows three alternative arrangements of surface enhancement features 42 within the core region 16. The illustrated arrays show preferred embodiments, namely; a square grid layout, a concentric circle layout, and a diamond grid layout. The distributed arrays of surface enhancement features 42 illustrated are micro-machined posts, fabricated from a highly conductive material. The shape, size and pitch of the surface enhancement features should be predetermined to provide a uniform flow resistance along all radial flow directions. The surface enhancement features 42 reduce the thermal resistance between the working fluid and the inner surfaces of the upper and lower plates by increasing the effective surface area for heat transfer.

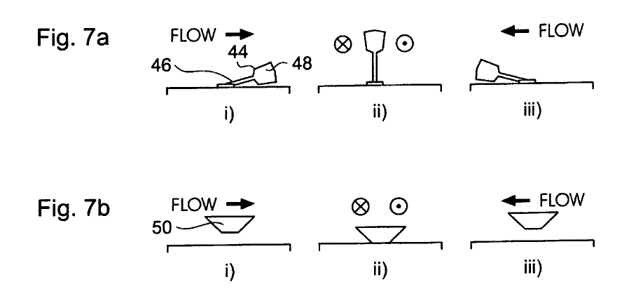

A heat shuttle is a type of surface enhancement feature which oscillates in position to dissipate heat into the working fluid 38. FIG. 7a depicts a side view of a first embodiment of a heat shuttle 44. The heat shuttle comprises a stem portion 46, attached via a hinged means to an inner surface of a active multi-phase heat spreader 10, and a head portion 48 attached to the terminal end of the stem portion 46. Specifically, FIG. 7a shows the heat shuttle position during three stages of a flow cycle. FIG. 7a.i) illustrates the heat shuttle position during cross flow, when the head portion 48 is in close proximity with an inner surface of the lower plate. Heat is loaded into the heat shuttle 44 from the inner surface. FIG. 7a.ii) illustrates the heat shuttle 44 position during parallel flow, when the stem portion 46 is normal to the inner surface of the lower plate. Heat is dissipated into the working fluid. FIG. 7a.iii) illustrates the heat shuttle position during cross flow in an opposite direction, and again the head portion 48 is in close proximity with an inner surface of the lower plate. Thus the heat shuttle oscillates, also known as shuttling, as the fluid flow in the fluidic gap 36 oscillates radially. In an active multi-phase heat spreader 10, the working fluid flow cycle illustrated in FIGS. 7a.i)-iii) can be denoted θ=3π/2, θ=0 or π, θ=π/2, respectively.

FIGS. 7b.i)-iii) illustrate an alternative heat shuttle structure 50. The embodiment illustrated shows a head portion with a trapezoidal cross section which is attached to a flexible stem portion (not illustrated). Forces created as the working fluid flows across the structure at certain angles during a flow cycle cause the head portion to be lifted, see FIG. 7b.i) and iii), and lowered, see FIG. 7b.ii). The flexible stem is attached to an inner surface of the heat spreader 10, but may flex to enable the raising and lowering of the head portion.

Preferably a thermal time constant of the heat shuttle structure, 44 or 50, is designed to correspond with the shuttling frequency. More design freedom in the thermal time constant of the heat shuttle structure, 44 or 50, can be achieved by providing a heat shuttle that shifts position at relatively smaller working fluid flow cycle stages, such as π/3, π/4 etc.

Various designs of heat shuttle can be envisaged comprising a mass that shuttles as the working fluid flow rotates through predetermined angles.

The heat shuttles, 44 or 50, may be positioned in an array in the core region 16 in a similar manner to the posts 42 described above. Such arrays should not lead to a preferred flow direction in any particular radial angle. Rather, the heat shuttles, 44 or 50, should provide a uniform flow resistance in all radial directions.

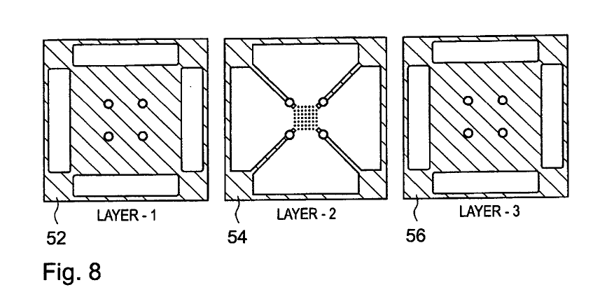

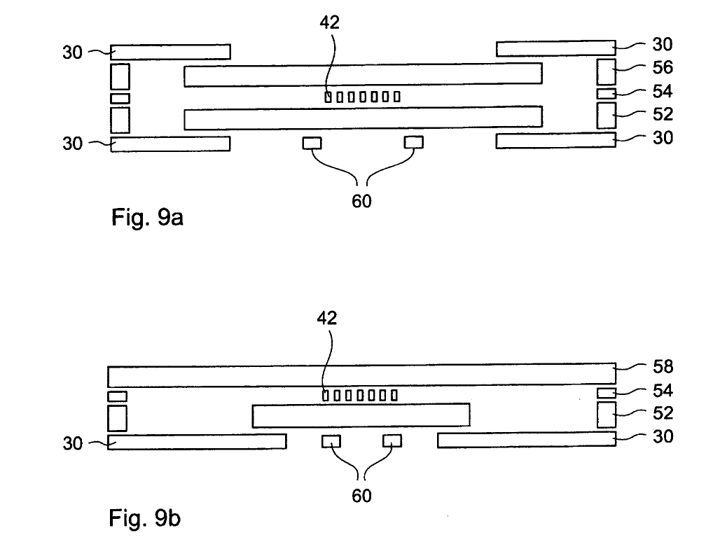

FIG. 8 shows a plan view of an exemplary embodiment of a series of patterned plate layers utilized in compiling an active two-phase heat spreader 10. Various planar fabrication techniques, such as microscale batch fabrication could be utilized to create the layers, 52, 54, 56, which are then stacked or bonded together. Polymer membranes 30 may be attached over both sides of the reservoir openings as illustrated in FIG. 9a. FIG. 9b illustrates an alternative layered active multi-phase heat spreader design involving a third layer of a non-patterned plate 58 and attaching polymer membranes 30 only over the reservoir opening on the first layer of a patterned plate 54. Standoffs 60, which are positioned between the carrier and active multi-phase heat spreader and function to support and separate these entities, are also illustrated.

In the present active multi-phase heat spreader concept, the relatively thin upper and lower plates, the distributed surface enhancement features in the core region, and the arrangement of spring loaded plungers in the mounting holes, combine to allow the heat spreader to deform to match the warpage of a cyclically-heated microprocessor chip. Advantageously, as the active multi-phase heat spreader deforms to match the warpage of a heated microprocessor chip, thermal energy transfer can continue and a small gap is maintained for a thermal interface material. Thus, “paste pumping” is reduced and a stress load associated with rigid solder or adhesive bonds is avoided.

A “deflection distance” is defined as the distance that working fluid is moved after a single pump action. This deflection distance can be calculated based on the volume change of the reservoir between a vented state and a filled state, and the cross sectional area of the fluidic gap. For a pair of oppositely-located reservoirs working together, where one of the reservoirs is venting and the other is filling, each with a membrane cross-sectional area Ar moving a through a distance dr and a corresponding active multi-phase heat spreader length with average cross-section of Aₛ, the fluid displacement length S in the spreader is:
S=dᵣAᵣ/Aₛ (5)

In a preferred embodiment of the active multi-phase heat spreader, the reservoirs and membrane actuation may be designed such that the volume of working fluid displaced by a pump action is adequate to move working fluid at least half the distance between oppositely located reservoirs. Thus, the required reservoir deflection for a known spreader length is:
dᵣ=SAₛ/Aᵣ (6)

In a preferred embodiment of the active multi-phase heat spreader, the membrane actuators may be designed to operate at a resonant frequency related to the elastic stiffness of the membrane 30 and the mass of working fluid 38 in oscillation in order to reduce the electrical power required by the pump action means. The resonant frequency preferably also corresponds to the operating frequency for maximum heat transfer from a fluidic heat transfer model such as equation 3.

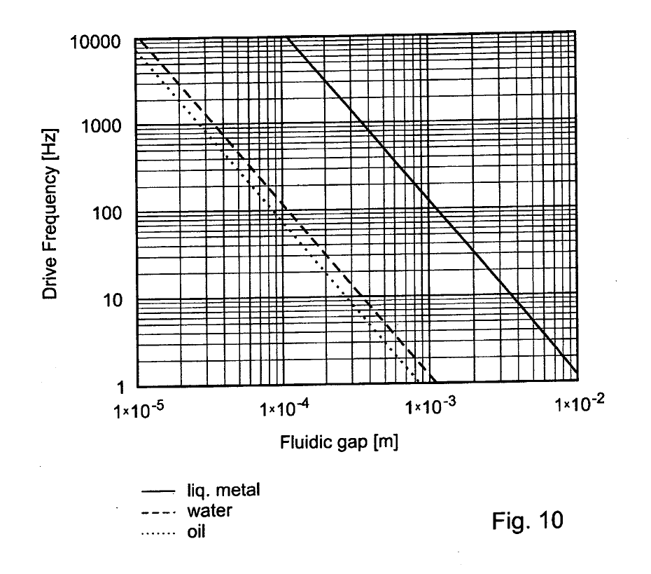

It is possible to determine a minimum membrane actuation frequency, or ‘drive frequency’, for a predetermined fluidic gap dimension and specific working fluid 38. Such a calculation is based on the previously recited equations characterizing undeveloped flow profiles. However, those equations are based on linear oscillating flow within channels of uniform cross section. Thus, the equations characterizing undeveloped flow profiles of the present active multi-phase heat spreader would be marginally different, due to the nozzle-like effect as working fluid passes through the restricted core region 16 and also the radial nature of the flow. FIG. 10 provides a graphical illustration of this information, showing the drive frequency in Hertz against the fluidic gap in meters for liquid metal, water and oil as working fluids. For example, where the working fluid is water sealed within a fluidic gap of approximately 0.0001 m, then the minimum drive frequency is approximately 100 Hertz. For a working fluid of oil sealed within a fluidic gap of approximately 0.0005 m, the minimum drive frequency is approximately 10 Hertz.

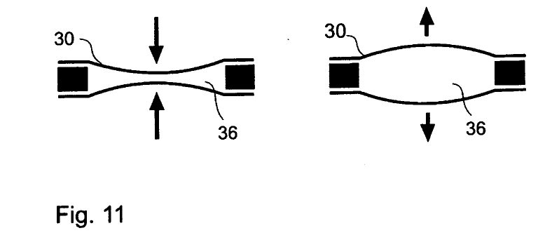

In the present active multi-phase heat spreader embodiment, the radially oscillating flow pattern is driven by membrane actuation causing a pump action. FIG. 11 illustrates a symmetric membrane actuation in the fluidic gap 36 of a reservoir 14, where the left diagram shows the reservoir in a vented state and the right diagram shows the reservoir in a filled state. Such symmetric membrane actuation may reduce vibration generated by the oscillating membranes 30, compared to an actuator embodiment having a single membrane 30. The membrane actuation may be performed by a solenoid or electrostatic forces or piezo layers on a membrane surface. Where the working fluid 38 is a conductive or magnetic liquid, then a magnetic pump action may be utilized. Also, in a further preferred embodiment, the membrane actuators may be designed to allow for the application of both push and pull forces, as indicated by the solid arrows in FIG. 11, to ensure reservoirs are vented and filled with an appropriate phase shift and without cross-talk between reservoirs.

Alternatives to various aspects of the above described embodiments of an active multi-phase heat spreader are envisioned. For example, it is also envisioned that the surface enhancement features can be fabricated on the inner surface of either or both of the upper and lower plates. The microprocessor chip and associated core region can be of various shapes in addition to the square shape of the illustrated embodiments. Whilst the embodiments described focus on heat spreader plates and reservoir covers—comprised of copper and polymer respectively, other suitable materials may be utilized. In addition to the possible pump action means previously recited, other known pump action means for membrane actuation can be utilized. Whilst a preferred embodiment of the heat spreader has a layer of thermal interface material between the microprocessor chip and the lower heat spreader plate, the provision of thermal interface material is optional.

It is envisioned that the above-disclosed heat shuttle concept may be utilized outside the confines of active multi-phase heat spreaders. For example, active single-phase heat spreaders have an oscillating flow similar to the oscillating flow of the active multi-phase heat spreader, and could therefore also utilize the heat shuttle concept. Further, microchannel cooling devices have a pulsing flow which is also suitable for heat shuttle implementation. Specifically, as the pulsing flow periodically reduces and surges, a heat shuttle may absorb and dissipate heat respectively. Further, any scenario requiring transfer of heat energy from a solid into a fluid, on any scale, may utilize this heat shuttle concept. Where the fluid has neither oscillating nor pulsing flow, then the heat shuttle may be mechanically moved between contact with the heated surface and the fluid. The scope of the use of the heat shuttles may extend to any scenario where transfer of heat from a solid body into a fluid is required.

It will be appreciated that the active multi-phase heat spreader of the present concept may be interfaced with a plurality of high power density devices, for example, high power laser and optics components or power electronics. Also, direct integration of the active multi-phase heat spreader to various devices may be realized.

Improvements and modifications can be made to the foregoing without departing from the scope of the present invention as set forth in the appended claims.

1. A heat spreader comprising:
a chamber comprising first surface, a second surface and chamber sides;
fluid sealed in said chamber, and
at least two actuators disposed within said chamber, whereby an operational phase of the actuators results in a substantially constant velocity of fluid flow across a core region of the heat spreader.

2. The heat spreader as claimed in claim 1, wherein the direction of the fluid flow changes radially.

3. The heat spreader as claimed in claim 2, wherein the at least two actuators comprise multiple actuators which drive a respective multi-phase flow cycle.

4. The heat spreader as claimed in claim 3 wherein the multiple actuators comprise four actuators which drive a two-phase flow cycle.

5. The heat spreader as claimed in claim 3 wherein the multiple actuators comprise six actuators which drive a three-phase flow cycle.

6. The heat spreader as claimed in claim 1, wherein each actuator comprises a reservoir of said fluid and a membrane interfacing between an actuation means and said reservoir.

7. The heat spreader as claimed in claim 6, wherein each actuator additionally comprises a further membrane positioned on an opposite side of said reservoir from said actuation means.

8. The heat spreader as claimed in claim 1, wherein the core region is positioned centrally within the chamber and the actuators are positioned at the periphery of the chamber.

9. The heat spreader as claimed in claim 1, wherein at least one surface enhancement feature is positioned on at least one of said first surface and said second surface.

10. The heat spreader as claimed in claim 9, wherein said at least one surface enhancement feature comprise a plurality of protrusions in a distributed arrangement to provide a substantially uniform flow resistance along all radial flow directions.

11. The heat spreader as claimed in claim 10 wherein said distributed arrangement is located at the core region.

12. The heat spreader as claimed in claim 9, wherein said at least one surface enhancement feature comprise at least one flow directing feature comprising a barrier positioned to provide substantially uniform flow of the fluid throughout the chamber.

13. The heat spreader as claimed in claim 12, wherein said at least one flow directing feature is located in an area between the core region and the actuators.

14. The heat spreader as claimed in claim 1 wherein the fluid is one of water, oil, a magnetic liquid and a conductive liquid.

15. The heat spreader as claimed in claim 9 wherein said at least one surface enhancement feature comprises a heat shuttle comprising a head portion fixed to one of said surfaces via a mobile stem portion, wherein said heat shuttle transfers thermal energy between said surface and fluid circulating around said head portion.

16. A method for transferring heat away from a heat source, the method comprising the steps of:
providing a chamber in thermal contact with the heat source, said chamber comprising a first surface, a second surface and chamber sides, fluid sealed in said chamber, and at least two actuators disposed in said chamber,
actuating said actuators such that the operational phase of the actuators results in a substantially constant velocity of fluid flow across a core region of the chamber.

17. The method as claimed in claim 16, wherein the direction of the fluid flow changes radially.

18. The method as claimed in claim 16, wherein the at least two actuators comprise multiple actuators which drive a respective multi-phase flow cycle.

19. The method as claimed in claim 16, further comprising providing at least one surface enhancement feature on at least one of said first surface and said second surface.

20. The method as claimed in claim 19, wherein said surface enhancement features are selected to provide a substantially uniform flow resistance along all radial flow directions.
